(19) United States
(12) Patent Application Publication
(10) Pub. No.: US 2011/0078523 A1
(43) Pub. Date: Mar. 31, 2011

(54) OUTPUT CONTROL SCAN FLIP-FLOP, SCAN TEST CIRCUIT USING THE SAME, AND TEST DESIGN METHOD

(75) Inventor: Mikihiro KANOMATA, Kanagawa (JP)

(73) Assignee: Renesas Electronics Corporation

(21) Appl. No.: 12/891,209

(22) Filed: Sep. 27, 2010

(30) Foreign Application Priority Data
Sep. 28, 2009 (JP) 2009-222296

(51) Int. Cl. G01R 31/3177; G06F 11/25

(52) U.S. Cl. 714/726; 714/E11.155

(57) ABSTRACT

An output control scan flip-flop according to an exemplary aspect of the present invention can control an output value to be held and inverted irrespective of an input value. The output control scan flip-flop includes a scan flip-flop; a storage element that operates in synchronization with a clock signal and stores first input data externally supplied; an exclusive-OR logic circuit that receives an output signal from the storage element and an output signal from the scan flip-flop; and a selector that receives second input date externally supplied, an output signal from the exclusive-OR logic circuit, and a select signal externally supplied, and supplies an output signal to the scan flip-flop.

### INCORPORATION BY REFERENCE

This application is based upon and claims the benefit of priority from Japanese patent application No. 2009-222296, filed on. Sep. 28, 2009, the disclosure of which is incorporated herein in its entirety by reference.

### BACKGROUND

1. Field of the Invention

This invention relates to a scan flip-flop used for a scan test of a semiconductor integrated circuit.

2. Description of Related Art

A scan test is one of design techniques that facilitate a test of a semiconductor integrated circuit. In the scan test, a flip-flop (FF) provided in the circuit is replaced with a scan FF.

FIG. 11 shows an exemplary construction of an inverting-holding type scan FF 101 in a prior art (Japanese Unexamined Patent Application Publication No. 2006-84403). The scan FF 101 includes a typical FF 102 and a selector 103. The selector 103 selects one of an output (Q terminal signal) of the FF 102, data (DATA IN terminal signal) from a combination circuit, and an inversion output (QB terminal signal) of the FF 102 according to a select signal (DELAY TEST MODE terminal signal) that controls the selection, and outputs the selected signal.

FIG. 12 shows an exemplary circuit using four scan FFs 101-1, 101-2, 101-3, and 101-4 in the prior art. In this circuit, a delay test controller 110 controls all the DERAY TEST MODE signals 111 to 114. For example, when the first scan FF 101-1 is brought into an inversion facilitating configuration mode and the second to fourth scan FFs 101-2-101-4 are brought into a holding facilitating configuration mode by the delay test controller 110, target paths S1, S2, S3, and S4 are ready to be tested. Further, when the third scan FF 101-3 is brought into an inversion mode and the first, second, and fourth scan FFs 101-1, 101-2, and 101-4 are brought into the holding facilitating configuration mode, target paths S6, S3, and S4 are ready to be tested. Similarly, the delay test can be carried out for target paths S5, S2, S3, S4, and S7, S4 and the like.

### SUMMARY

The present inventor has found a following problem. The above-mentioned scan FF 101 requires the delay test controller 110 that controls the DELAY TEST MODE signal per bit for holding or inverting the output. This causes, there is a problem that the circuit size increases.

A first exemplary aspect of the present invention is an output control scan flip-flop that can control an output value to be held and inverted irrespective of an input value, including a scan flip-flop; a storage element that operates in synchronization with a clock signal, and stores first input data externally supplied; an exclusive-OR logic circuit that receives an output signal from the storage element and an output signal from the scan flip-flop; and a selector that receives second input date externally supplied, an output signal from the exclusive-OR logic circuit, and a select signal externally supplied, and supplies an output signal to the scan flip-flop.

A second exemplary aspect of the present invention is an output control scan flip-flop that can control an output value to be held and inverted irrespective of an input value, including a scan flip-flop; a storage element that operates in synchronization with a clock signal, and stores first input data from externally supplied; and a selector that receives second input data from externally supplied, an output signal from the storage element, and a select signal externally supplied, and supplies an output signal to the scan flip-flop.

A third exemplary aspect of the present invention is a scan test circuit including the output control scan flip-flop according to the first aspect of the present invention, in which the output control scan flip-flop is arranged at a start-point of a scan flip-flop positioned at an end-point of a path subjected to a transition delay test.

A fourth exemplary aspect of the present invention is a test design method for the scan test circuit according to the third exemplary aspect of the present invention including searching a path to be subjected to the transition delay test; and replacing a scan flip-flop arranged at a start-point of a scan flip-flop positioned at an end-point of the path with the output control scan flip-flop.

According to the above-mentioned aspects, by controlling the select signal or the like to the selector, it is possible to deactivate a path other than a path to be subjected to the transition delay test, and to reliably transmit the delay signal in the path to be tested.

According to the present invention, it is possible to dispense the delay test controller controlling the DELAY TEST MODE signal, a plurality of DELAY TEST MODE signal lines or the like. Therefore, the scale of the circuit can be reduced.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing a construction of an output control scan flip-flop according to a first exemplary embodiment of the present invention;

FIG. 2 is a diagram showing an exemplary circuit in which the output control scan flip-flops according to the first exemplary embodiment are inserted as test points;

FIG. 3 is a timing chart in the case where a transition delay test for the circuit shown in FIG. 2 is carried out;

FIG. 4 is a flow chart showing a processing for inserting the output control scan flip-flop as the test point for the circuit shown in FIG. 2;

FIG. 5 is a flow chart showing an exemplary processing of step S103 shown in FIG. 4;

FIG. 6 is a diagram showing a construction of a circuit according to a second exemplary embodiment of the present invention;

FIG. 7 is a flow chart showing a processing for inserting the output control scan flip-flop as the test point for the circuit shown in FIG. 6;

FIG. 8 is a flow chart showing an exemplary processing of step S206 shown in FIG. 7;

FIG. 9A is a flow chart showing an exemplary processing of step S208 shown in FIG. 7;

FIG. 9B is a flow chart showing an exemplary processing of step S208 shown in FIG. 7;

FIG. 9C is a flow chart showing an exemplary processing of step S208 shown in FIG. 7;

FIG. 10 is a diagram showing a construction of an output control scan flip-flop according to a third exemplary embodiment of the present invention;

FIG. 11 is a diagram showing an exemplary inverting maintaining mixture type scan flip-flop in a prior art; and

FIG. 12 is a diagram showing an exemplary circuit using the four inverting maintaining mixture type scan flip-flop in the prior art.

### DETAILED DESCRIPTION OF THE EXEMPLARY EMBODIMENTS

### First Exemplary Embodiment

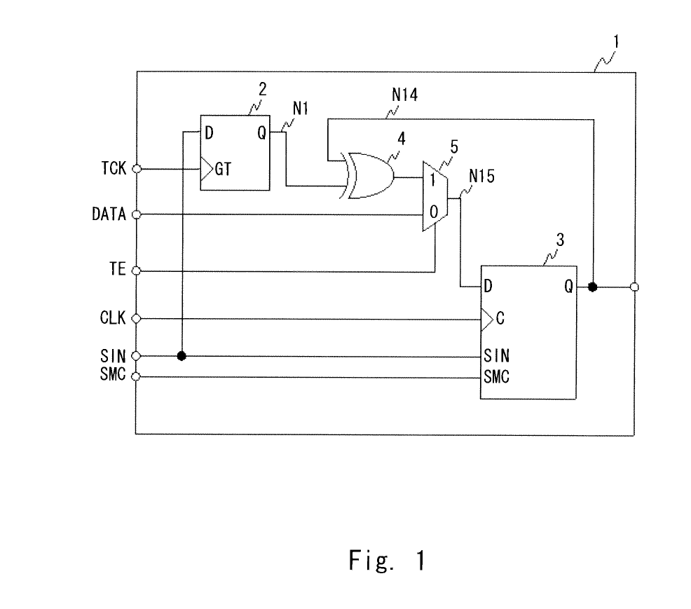

FIG. 1 shows a construction of an output control scan FF 1 according to a first exemplary embodiment of the present invention. The output control scan FF 1 includes a storage element 2, a scan FF 3, an exclusive-OR logic circuit 4, and a selector 5.

The storage element 2 stores input data from a scan shift input SIN in synchronization with a clock TCK. The exclusive-OR logic circuit 4 receives an output signal from the storage element 2 via a net N1 and an output signal from the scan FF 3 via net N14. The selector 5 receives DATA supplied from the outside of the output control scan FF 1 and an output of the exclusive-OR logic circuit 4, and uses a TE signal as a select signal. A net N15 that is an output signal of the selector 5 connects to a data input D of the scan FF 3. When the TE is “0”, the DATA is selected as the data input to the scan FF 3, and CLK, SIN, and SMC of the scan FF 3 receive signals externally supplied.

The output control scan FF 1 maintains or inverts the output of the output control scan FF 1 by the combination of the SIN, TCK, and TE, and carries out the operation similar to the general scan FF. In a case where the output of the scan FF 3 is maintained or inverted at a timing of the next CLK after the output of the scan FF 3 is set, the TE is set to “1”, and the scan FF 3 is set to a scan shift mode. Therefore, the input data from the SIN is stored in the storage element 2 at the timing of the TCK, and then, the input data from the SIN is set to the scan FF3 at the timing of the CLK. After that, the SMC is set to “0” so as to restore the scan FF3 from the scan shift mode to a normal mode. On the other hand, when the output control scan FF 1 carries out the operation similar to that of the general scan FF, the TE is set to “0”, the selector 5 receives the DATA, and the scan FF 3 receives the DATA at the timing of the CLK.

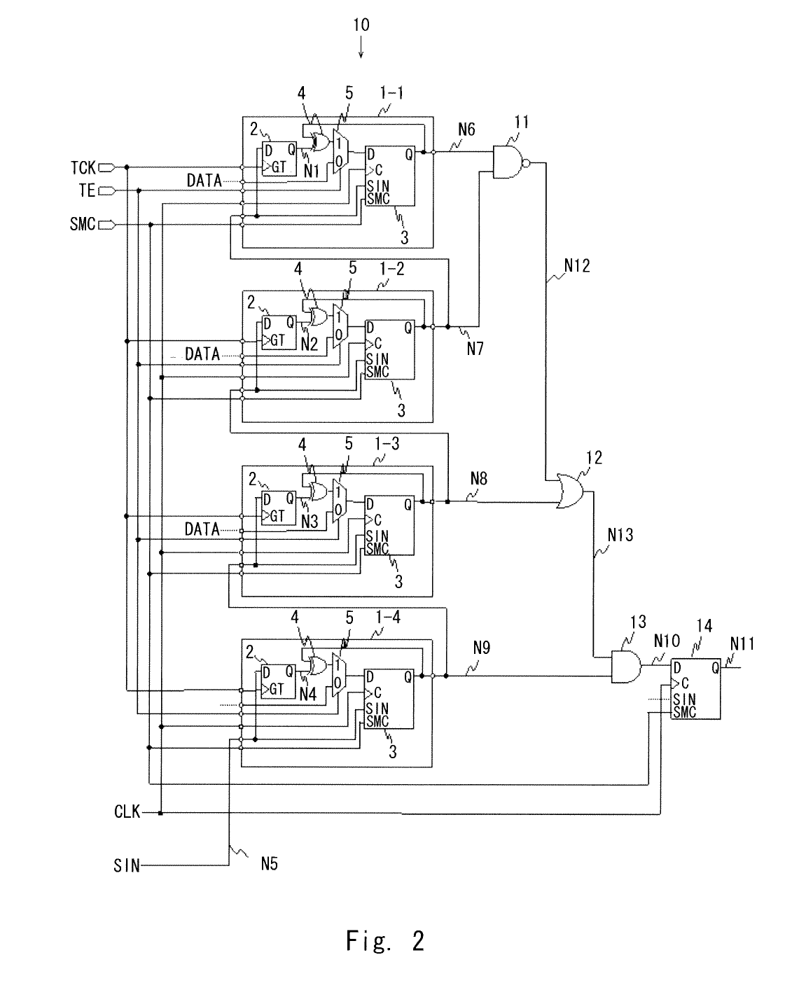

FIG. 2 shows an exemplary circuit 10 in which the output control scan FFs 1 are inserted as test points. The circuit 10 includes four output control scan FFs 1-1, 1-2, 1-3, and 1-4, a NAND circuit 11, an OR circuit 12, an AND circuit 13, and a scan FF 14. Each of N1, N2, N3, N4, N5, N6, N7, N8, N9, N10, N11, N12, and N13 represents a net.

The circuit 10 is a circuit in which all the scan FFs arranged at start-points of the scan FF 14 are replaced with the output control scan FFs 1 in the case of the transition delay test for certain paths using the scan FF 14 as an end-point. The scan FF arranged at the start-point of the scan FF 14 directly connects to a data input side of the scan FF 14 or connects via the combination circuit (the NAND circuit 11, the OR circuit 12, the AND circuit 13, or the like). The above-mentioned replacement with the output control scan FFs 1 is done to make these scan FFs controllable at the time of the transition delay test. Additionally, such a replacement may be done only in a part corresponding the target paths that cannot be subjected to the transition delay test. Further, any number of the TEs and the TCKs of all output control scan FFs 1-1, 1-2, 1-3, and 1-4 can be grouped together. Furthermore, the TE and the TCK may be controlled directly via an exclusive external terminal, or may be controlled by a simple control circuit provided in an LSI by sharing another external terminal. FIG. 2 shows a configuration in which the TEs and the TCKs are grouped and directly controlled via the exclusive external terminal.

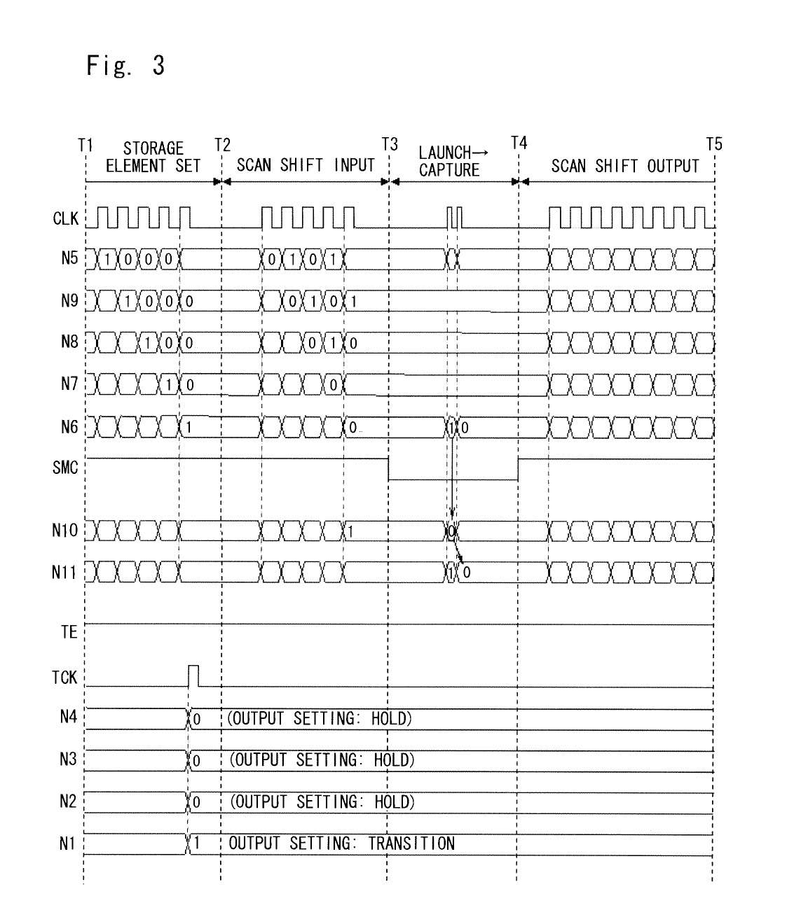

FIG. 3 shows a timing chart in the case where the transition delay test is carried out for the target path of N6→N12→N13→N10→ the scan FF 14 in the circuit 10. First, in order to control the output of each of the output control scan FFs 1-1, 1-2, 1-3, and 1-4, the TE is set to “1”, each of the storage elements 2 receives a value for setting to maintain or invert the output as a scan shift pattern from the SIN, and the value is set at the timing of the TCK. In this case, in order to transit only the net N6 as the start-point of the transition delay test, and to maintain the value of the output control scan FFs 1-2, 1-3, and 1-4 connected to the nets N7 to N9, the value “1” for inverting the output is set to a storage element P2 of the output control scan FF 1-1 connected to the net N6, and the value “0” for holding the output is set to a storage element P2 of the output control scan FFs 1-2, 1-3, and 1-4 (refer to T1-T2).

Next, a value necessary for the activation and transition of the target paths of the transition delay test is set to each of the output control scan FFs 1-1, 1-2, 1-3, and 1-4 by an ordinary input operation for the scan shift. FIG. 3 shows a case where the transition delay test from “1” to “0” is carried out for the target path that reaches the scan FF 14 via the N6, N12, N13, and N10. In order to activate the target path, “1” is set to the output control scan FF 1-2 connected to the net N7, “0” is set to the output control scan FF 1-3 connected to the net N8, “1” is set to the output control scan FF 1-4 connected to the net N9, and “1” before transition of the transition delay test is set to the output control scan FF 1-1 connected to the net N6 (refer to T2-T3).

Next, the transition delay test is carried out by a launch and a capture operation of the ordinary scan. The net N6 transits to “0” from “1” according to the CLK in the launch state, and the net N6 transits to “1” from “0” according to the CLK in the capture state. The transition delay test is conducted such that the scan FF 14 receives the value at the time when the net N6 transits to the “0” at the timing of the CLK in the capture state of the scan FF 14 (refer to T3-T4).

Finally, in order to confirm whether the value at the time when the net N6 transits to “0” is properly received by the scan FF 14, the value received by the scan FF 14 is output to the outside by the ordinary scan shift output, and is confirmed (refer to T4-T5). Thus, by the operation during T1 to T2, the transition delay test may be carried out by the ordinary scan operation after all of the start-points of the scan FF 14 are controlled by the output control scan FFs 1-1, 1-2, 1-3, and 1-4. Additionally, when it is possible to prepare a shift pattern that can set the value of each storage element 2 and the scan shift of the ordinary scan pattern at the same time, the setting of the value for each storage element 2 (T1-T2) and the setting of the ordinary scan shift (T2-T3) may be carried out at the same time.

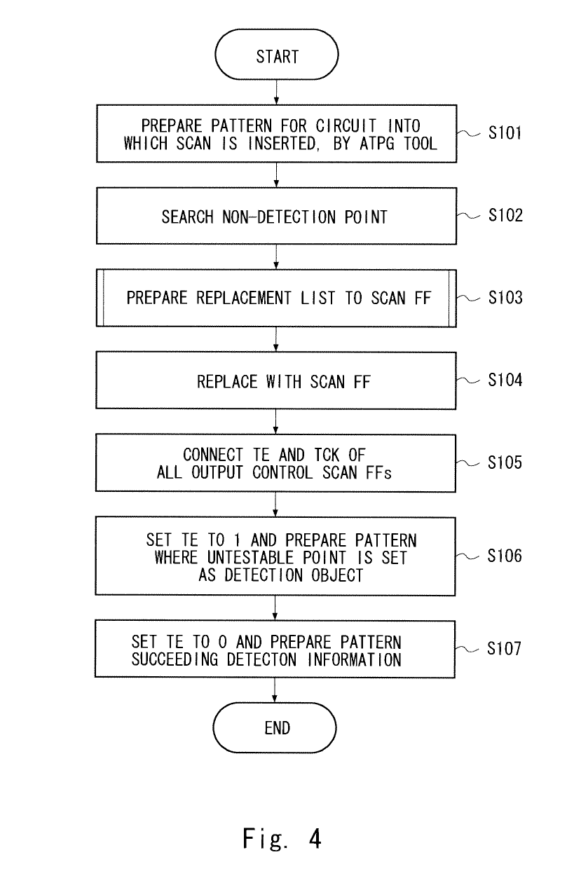

FIG. 4 shows a processing for inserting the output control scan FF 1 to the circuit 10 as the test point, the circuit 10 is already inserted the scan. First, for the circuit 10, the scan pattern is prepared by an ATPG (Automatic Test Pattern Generator) tool (step S101). Next, a point which is uncontrollable by the ATPG tool or which cannot be tested because the analysis is not finished is searched as a non-detection point (step S102). Next, a list (hereinafter referred to as a replacement list) is prepared. The replacement list contains the scan FFs that are to be replaced with the output control scan FF 1 among the scan FFs of the circuit 10 (step S103). Then, the scan FF is replaced with the output control scan FF 1 according to the replacement list (step S104).

Next, the terminals of each of the TE and TCK of the output control scan FFs 1 replaced are connected so that the terminals can be collectively controlled (step S105). Next, the terminal of the TE of the output control scan FF 1 is set to “1”, and the scan pattern is prepared by the ATPG tool (step S106). Finally, the ordinary scan pattern is prepared by succeeding a failure detection result prepared by the step S106 (step S 107).

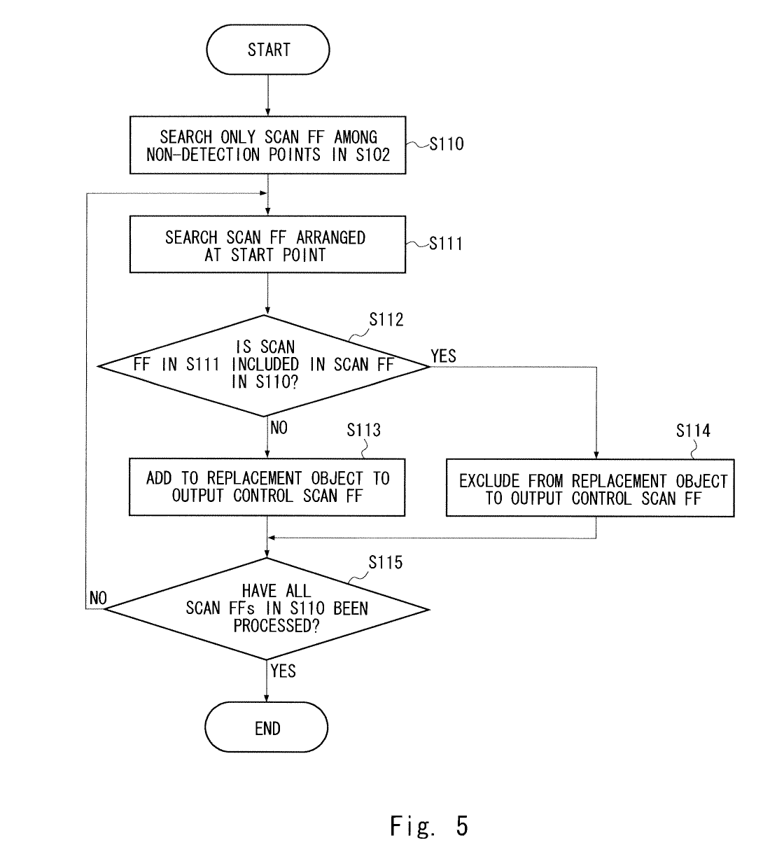

FIG. 5 shows a concrete processing example of the step S103. First, only the scan FF is searched from the non-detection points searched in the step S102 (step S110). Next, the scan FF arranged at the start-point is searched according to the searched scan FF (step S110).

Next, it is confirmed whether the searched scan FF arranged at the start-point is included in the scan FFs searched in the step S110 (step S112). In the step S112, when it is decided that the scan FF arranged at the start-point is not included in the scan FFs searched in the step S110 (NO), the scan FF arranged at the start-point becomes a candidate for the replacement with the output control scan FF 1 (step S113). On the other hand, when it is decided that the scan FF arranged at the start-point is included in the scan FFs searched in the step S110 (YES), this scan FF arranged at the start-point is excluded from the candidate for the replacement with the output control scan FFs because the scan FF arranged at the start-point is the end-point of the target path (step S114).

Then, it is decided whether the decision of the replacement about all the scan FFs searched in the step S110 is completed (step S115). When it is not competed (NO), the steps S111-S115 are repeated, and when it is completed (YES), the process is finished.

As mentioned above, the output control scan FF 1 according to this exemplary embodiment includes the storage element 2 that stores the input data from the scan shift input SIN at the timing of the TCK, and the exclusive-OR logic circuit 4 that inverts or non-inverts the output from the scan FF 3 depending on the value stored in the storage element 2. By replacing all the scan FFs arranged at the start-points of the scan FF 14 as the end-point of the target paths with the output control scan FFs 1, the path other than the target path can be activated and the transition of the signal in the target path can be reliably carried out when the transition delay test is carried out. This eliminates the need to provide, the delay test controller and the plurality of the delay test mode signal lines which are necessary for the conventional scan FF including both mechanisms for maintaining/inverting an output.

### Second Exemplary Embodiment

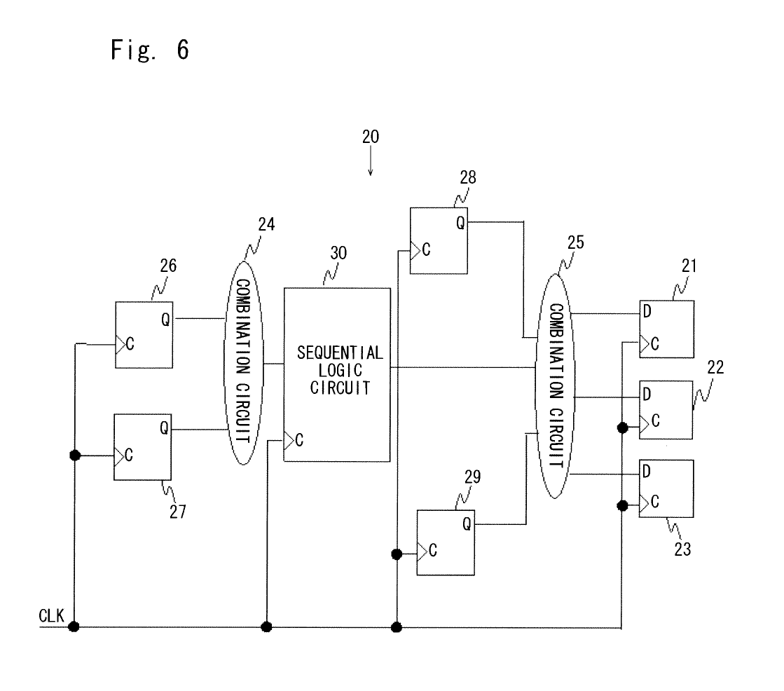

FIG. 6 shows a construction of a circuit 20 according to a second exemplary embodiment of the present invention. The circuit 20 includes general scan FFs 21, 22, 23, 26, 27, 28, and 29, combination circuits 24 and 25 and a sequential logic circuit 30. A ROM, a RAM, an IP core, or the like corresponds to the sequential logic circuit 30.

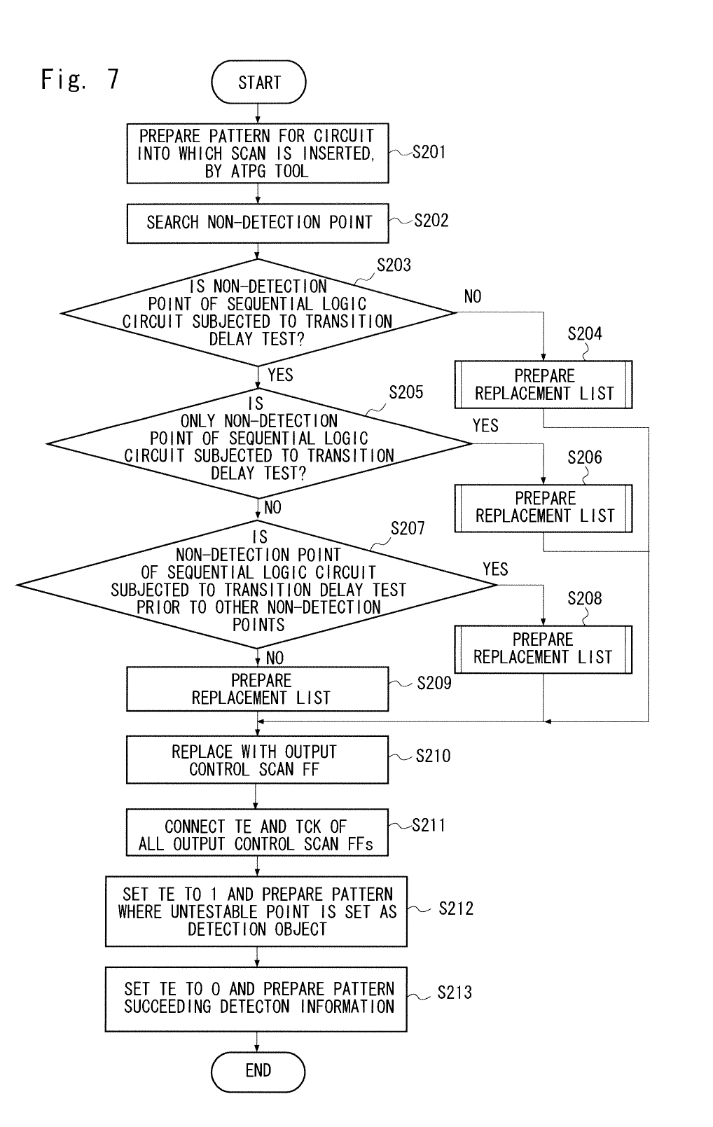

FIG. 7 shows a processing for inserting the output control scan FF 1 into the circuit 20 as a test point. First, for the circuit 20 in which the scan has already been inserted, the scan pattern is prepared by the ATPG tool (step S201). Next, a point which is uncontrollable by the ATPG tool or which cannot be tested because the analysis is not finished is searched as a non-detection point (step S202).

Next, it is decided whether the sequential logic circuit 30 included in the searched non-detection point is subjected to the transition delay test (step S201). In the step S203, when the sequential logic circuit 30 is not subjected to the transition delay test (NO), the replacement list with the output control scan FF 1 is prepared (step S204), and the replacement with the output control scan FF 1 is carried out (step S210). On the other hand, in the step S203, when the sequential logic circuit 30 is subjected to the transition delay test (YES), it is decided whether only the non-detection point of the sequential logic circuit 30 is to be replaced with the output control scan FF1 (step S205).

In the step S205, when only the non-detection point of the sequential logic circuit 30 is to be replaced (YES), the replacement list with the output control scan FF 1 is prepared (step S206), the replacement to the output control scan FF 1 is carried out (S210). On the other hand, in the step S205, when not only the non-detection point but also other non-detection points are to be replaced with the output control scan FF 1 (NO), it is decided whether the non-detection point of the sequential logic circuit 30 is subjected to the transition delay test prior to other non-detection points (step S207).

In the step S207, when the other non-detection point is given priority (YES), the replacement list with the output control scan FF 1 is prepared (step S208), and the replacement with the output control scan FF 1 is carried out (step S210).

After that, the terminal of each TE of the replaced output control scan FF 1 and the terminal of each TCK thereof are connected (step S211), Next, the terminal of the TE of the output control scan FF 1 is set to “1”, and a scan pattern is prepared by the ATPG tool (step S212). Finally, a general scan pattern is prepared by succeeding a failure detection result prepared in the step S212 (step S213).

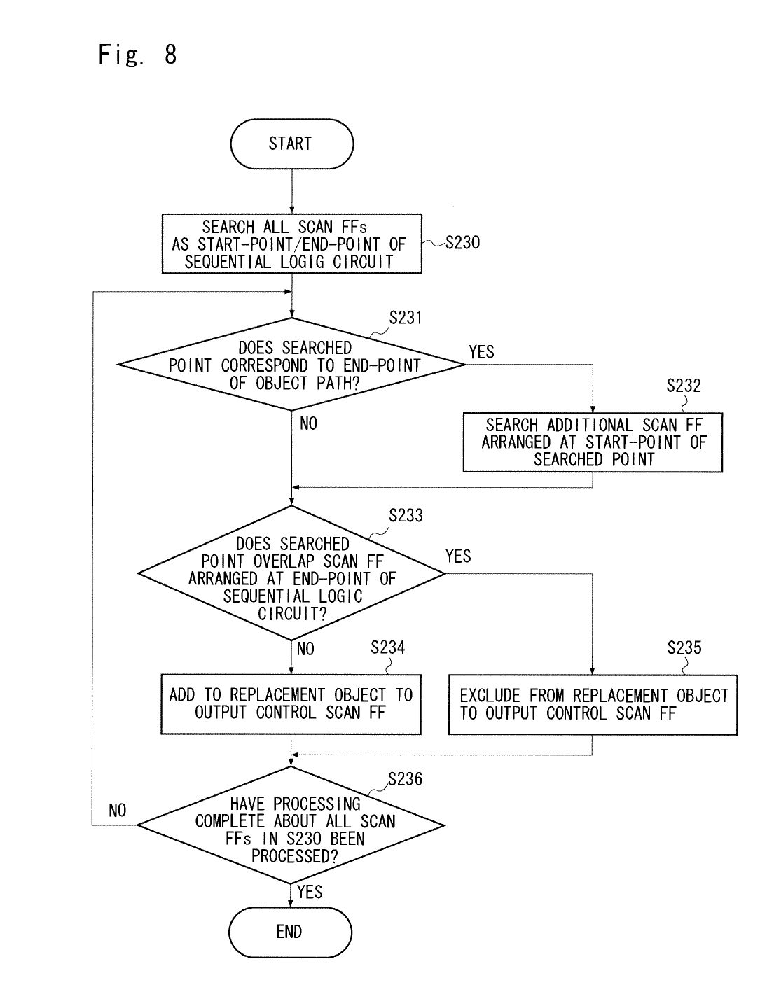

FIG. 8 shows a concrete processing example the step S206 (refer to FIG. 7). First, all of the scan FFs that are arranged at the start-point/end-point of the sequential logic circuit 30 are searched (step S230). Next, it is confirmed whether the searched scan FF is arranged at the end-point of the target path of the transition delay test (step S231). In the step S231, when the searched scan FF is arranged at the end-point (YES), the scan FF arranged at the start-point is added to the searched point (step S232).

In the step S231, when the searched scan FF is not arranged at the end-point (NO), or after the processing in the step S232 is finished, it is decided whether the scan FF searched in the step S230 or the step S232 overlaps the scan FF arranged at the end-point of the sequential logic circuit 30 (step S233). In the step S233, when no overlaps occurs (NO), the searched scan FF is to be replaced with the output control scan FF 1 (step S234). On the other hand, when overlap occurs (YES), the searched scan FF is excluded from the replacement target (step S235).

After that, it is decided whether the processing for all the scan FFs searched in the step S230 has been completed (step S236). When it has not been completed yet (NO), the process returns to the step S231, and when it has been completed (YES), this routine is finished.

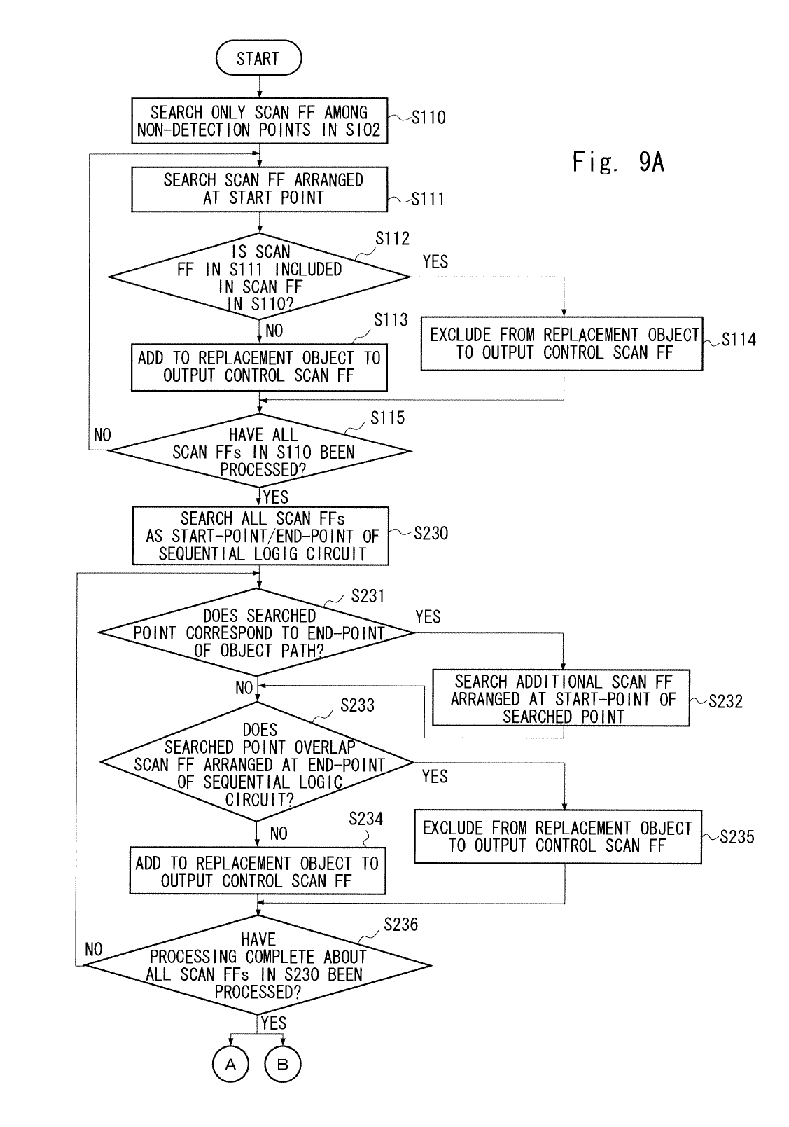

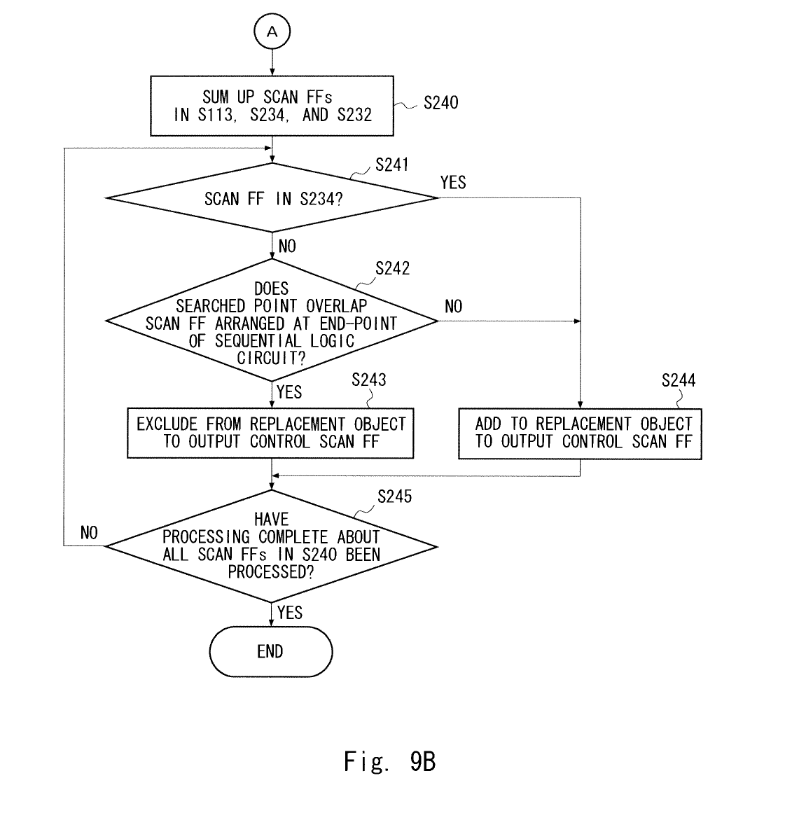

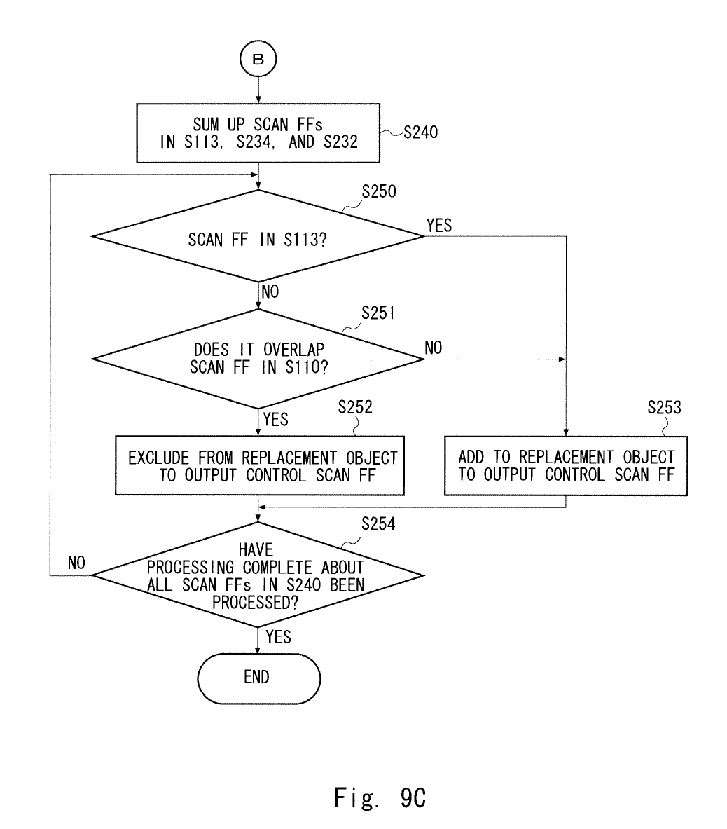

FIGS. 9A to 9C show a concrete processing example of the step S208 (refer to FIG. 7). This processing includes the steps S110-S115 shown in FIG. 5 and the steps S230-S236 shown in FIG. 8. The explanation of these processings is omitted. The processing shown in FIG. 9A to 9C continues to one of a first exemplary processing shown in FIG. 9B and a second exemplary processing shown in FIG. 9C after it is decided as “YES” in the step S236.

First, the first exemplary processing shown in FIG. 9B is explained. After it is decided as “YES” in the step S236, the replacement target in the step S113, the replacement target in the step S234, and the scan FF searched in the step S232 are summed up, and these are set as candidates for replacement with the output control scan FF 1 (step S240).

Next, it is confirmed whether the scan FFs which are set as the candidates for replacement in the step S240 are the scan FFs added in the step S234 (step S241). When they are the added scan FFs (YES), they are replaced with the output control scan FFs 1 (step S244). On the other hand, in the step S241, when they are not the added scan FFs (NO), it is confirmed whether the scan FFs which are set as the candidates in the step S240 overlap the scan FFs arranged at the end-point of the sequential logic circuit 30 (step S242).

In the step S242, when it is decided that overlap occurs (YES), the scan FFs which have become the candidates for replacement in the step S240 are excluded from the target of replacement with the output control scan FFs 1 (step S243), on the other hand, when it is decided that no overlap occurs (NO), the scan FFs which have become the candidates for replacement are added to the replacement target (step S244). After that, the processings of steps S241-244 are repeated until the processings for all the scan FFs which have become the replacement candidates in the step S240 are completed (step S245).

Next, the second exemplary processing shown in FIG. 9C is explained. After it is decided as “YES” in the step S236 (refer to FIG. 9A), the replacement object in the step S113, the replacement object in the step S234, and the scan FF searched in the step S232 are summed up, and these are set as candidates for replacement with the output control scan FF 1 (step S240).

Next, it is confirmed whether the scan FFs which have become the replacement candidates in the step S240 are the scan FFs added in the step S113 (step S250). When they are the added scan FFs (YES), they are set as the candidates for replacement with the output control scan FFs 1 (step S253). On the other hand, in the step S250, when they are not the added scan FFs (NO), it is confirmed whether the scan FFs which have become the replacement candidates in the step S240 overlap the scan FFs searched in the step S110 (step S251).

In the step S251, when it is decided that overlap occurs (YES), the scan FFs which have become the replacement candidates in the step S240 are excluded from the replacement target with the output control scan FF 1 (step S252). ON the other hand, when it is decided that no overlap occurs (NO), the scan FFs which have become the replacement candidates are added to the replacement target (step S253). After that, the steps S250 to S253 are repeated until the processings for all the scan FFs which have become the candidates in the step S240 are completed (step S254).

Further, the step S204 shown in FIG. 7 can be performed by the processing similar to that of the flow chart shown in FIG. 5.

According to the above-mentioned construction, not only the general scan FFs 21, 22, 23, 26, 27, 28, and 29 but also the circuit 20 including the sequential logic circuit 30 such as the ROM, RAM, or IP core can be subjected to the transition delay test.

### Third Exemplary Embodiment

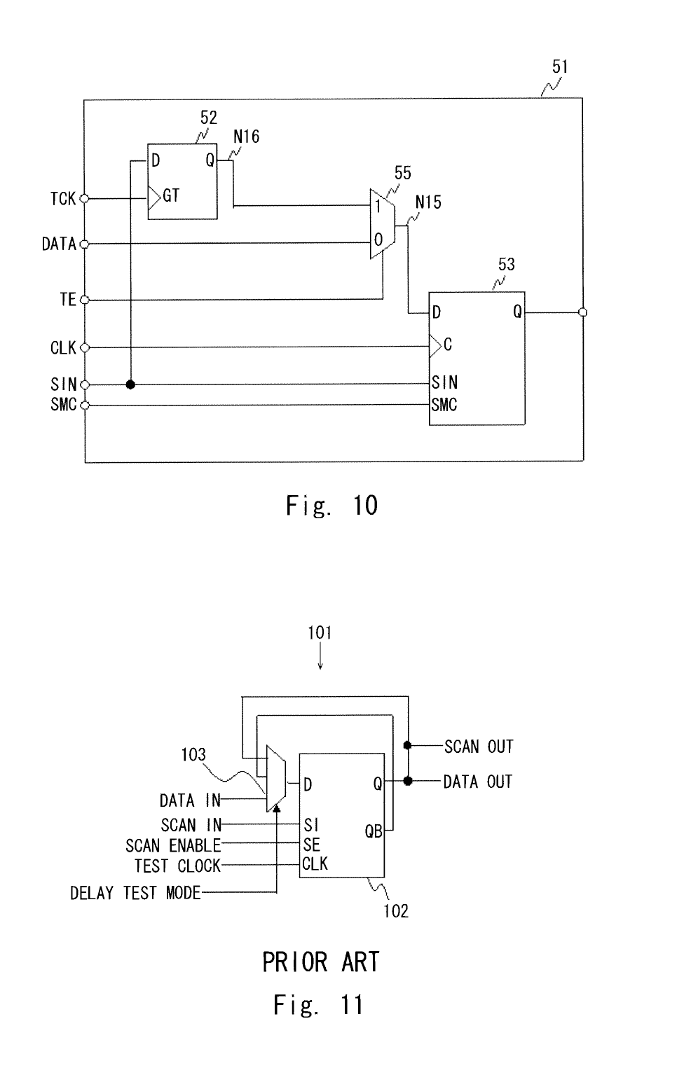

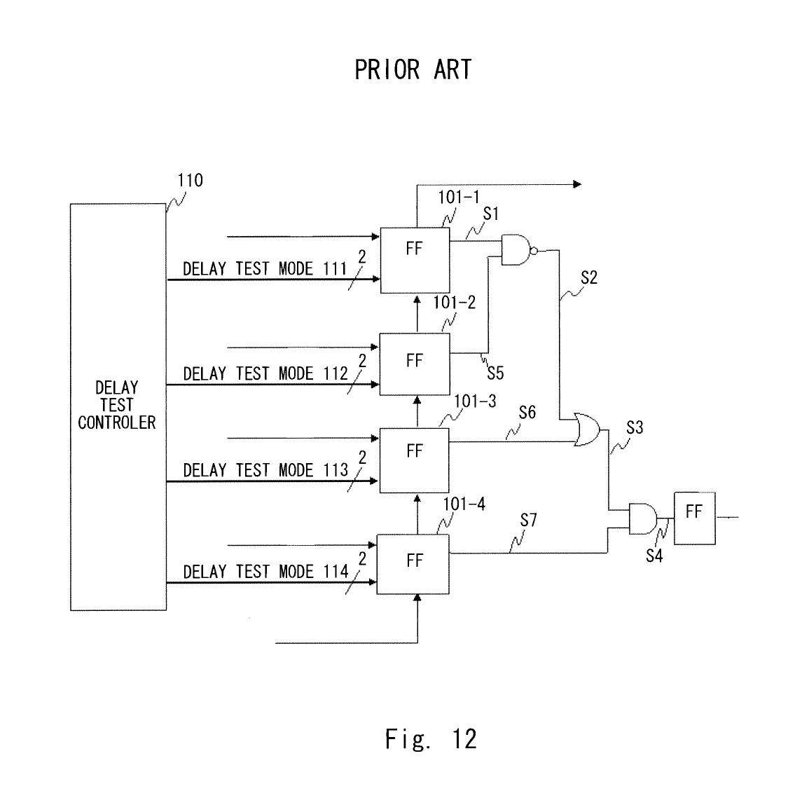

FIG. 10 shows a construction of an output control scan FF 51 according to a third exemplary embodiment. The output control scan FF 51 includes a storage element 52, a scan FF 53, and a selector 55. The storage element 52 stores input data from the scan shift input SIN in synchronization with the clock TCK. The selector 55 receives an output signal from the storage element 52 via a net N16, and receives DATA as a signal externally supplied, and assumes TE as a select signal.

When the TE is “1”, the selector 55 supplies an output signal to a data input D of the scan FF 53 via a net N15. This output signal is output by the storage element 52 to the net N16. On the other hand, when the TE is “0”, the selector 55 supplies the DATA to the data input D of the scan FF 53, and CLK, SIN, and SMC of the scan FF 53 receive signals externally supplied.

Even when the output control scan FF 51 having the above-mentioned structure is replaced with the output control scan FF 1 arranged in the circuit 10 shown in FIG. 2, the transition delay test can be carried out likewise. Further, without depending on the scan pattern, it is possible to set a necessary value beforehand at a desired time. In this case, it can also be used for an analysis other than the transition delay test.

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An output control scan flip-flop that can control an output value to be held and inverted irrespective of an input value, comprising:
a scan flip-flop;
a storage element that operates in synchronization with a clock signal, and stores first input data externally supplied;
an exclusive-OR logic circuit that receives an output signal from the storage element and an output signal from the scan flip-flop; and
a selector that receives second input date externally supplied, an output signal from the exclusive-OR logic circuit, and a select signal externally supplied, and supplies an output signal to the scan flip-flop.

2. An output control scan flip-flop that can control an output value to be held and inverted irrespective of an input value, comprising:
a scan flip-flop;
a storage element that operates in synchronization with a clock signal, and stores first input data from externally supplied; and
a selector that receives second input data from externally supplied, an output signal from the storage element, and a select signal externally supplied, and supplies an output signal to the scan flip-flop.

3. The output control scan flip-flop according to claim 1, wherein the scan flip-flop operates in synchronization with a first clock signal, and the storage element operates in synchronization with a second clock signal.

4. A scan test circuit comprising the output control scan flip-flop according to claim 1, wherein the output control scan flip-flop is arranged at a start-point of a scan flip-flop positioned at an end-point of a path subjected to a transition delay test.

5. The scan test circuit according to claim 4, wherein the first input data is a scan shift chain signal for the transition delay test.

6. The scan test circuit according to claim 5, further comprising a control unit that executes a first mode for maintaining or inverting a value supplied in a previous clock cycle based on a value stored in the storage element irrespective of the second input data; and a second mode for supplying the second input data.

7. A test design method for the scan test circuit according to claim 4 comprising:
searching a path to be subjected to the transition delay test; and
replacing a scan flip-flop arranged at a start-point of a scan flip-flop positioned at an end-point of the path with the output control scan flip-flop.

8. The test design method according to claim 7, further comprising:
replacing, when a sequential logic circuit except the scan flip-flop is included in the path, a scan flip-flop except the scan flip-flop arranged at the end-point of the sequential logic circuit among a plurality of scan flip-flops arranged at the start-point of a non-detection point of the sequential logic circuit with the output control scan flip-flop.

9. The test design method according to claim 8, further comprising:
determining which of the non-detection point among the scan flip-flops and the non-detection point of the sequential logic circuit is given priority to be replaced.
